(19) United States
(12) Patent Application Publication
(10) Pub. No.: US 2009/0245807 A1
(43) Pub. Date: Oct. 1, 2009

(54) OPTICAL POWER MONITORING CIRCUIT, OPTICAL TRANSCEIVER, OPTICAL MODULE, OPTICAL RECEIVER, AMPLIFIER CIRCUIT, AND INTEGRATED CIRCUIT

(76) Inventor: RINTARO NOMURA, Tokyo (JP)

Correspondence Address: NEC CORPORATION OF AMERICA, 6535 N. STATE HWY 161, IRVING, TX, 75039, US

(21) Appl. No.: 12/408,184

(22) Filed: Mar. 20, 2009

(30) Foreign Application Priority Data
Mar. 25, 2008 (JP) 2008-078004

(51) Int. Cl. H04B 10/00; H04B 10/06; H01S 5/50

(52) U.S. Cl. 398/135; 398/202; 359/333

(57) ABSTRACT

Optical power monitoring capable of achieving a wide dynamic range and high-speed response is realized. An optical power monitoring circuit includes: a first amplifier (TIA 2) that amplifies an input current from a light-receiving element (PD 1) with a variable gain to convert the current into a voltage signal; a second amplifier (LIM 3) that amplifies the output of the first amplifier to convert the output into a main signal output; a third amplifier (AMP 4) that amplifies the output of the first amplifier with a variable gain to convert the output into a monitor output; and a gain variable means (amplifier comparator 5) for changing the gain of the first amplifier and gain of the third amplifier depending on the output of the first amplifier.

This present application is based upon and claims the benefit of priority from Japanese patent application No. 2008-078004, filed on May 25, 2008, the disclosure of which is incorporated herein in its entirety by reference.

### TECHNICAL FIELD

The present invention relates to an optical power monitoring circuit, an optical transceiver, an optical module, an optical receiver, an amplifier circuit, and an integrated circuit and, more particularly, to an optical power monitoring circuit that is provided in an optical module having a receiver function and measures received optical power over a wide dynamic range and at high speed.

### BACKGROUND ART

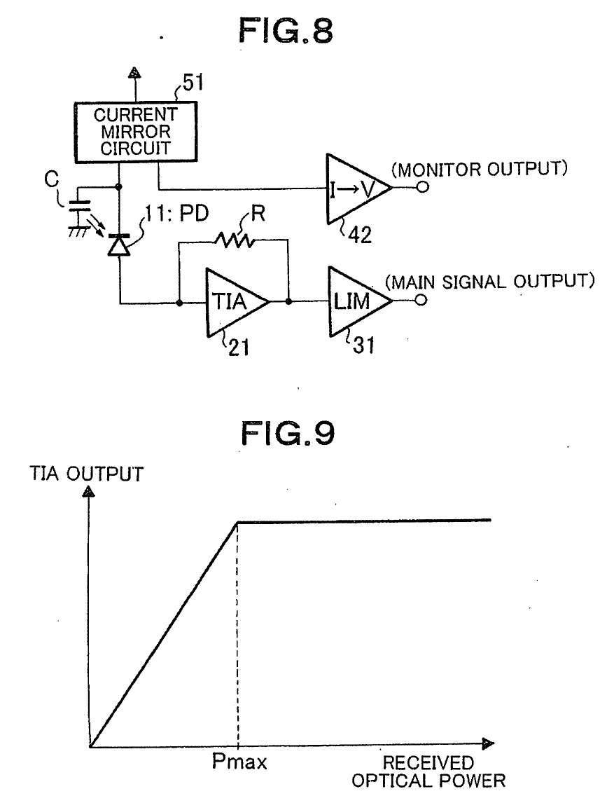

In the field of optical communication, an optical transceiver which is an optical module obtained by integrating an optical receiver (optical receiving circuit, optical receiving module) that receives light and converts the light into an electrical signal and an optical transmitter (optical transmitting circuit, optical transmitting module) that converts an electrical signal into light for transmission has come to be adopted for achievement of a reduction in the size of the apparatus and cost. A configuration example of a related art concerning an optical receiving circuit of such an optical module is shown in FIGS. 7 and 8.

An optical receiving circuit according to a first related art shown in FIG. 7 has a photo diode (PD) 11 serving as a light receiving element that converts light into a current signal, a transimpedance amplifier (TIA) 21 serving as a preamplifier that receives the current signal from the PD 11 and amplifies the current signal with a gain proportional to a value of a feedback resister R to convert it into a voltage signal, a limiting amplifier (LIM) 31 serving as a post amplifier that amplifies the TIA output to a prescribed amplitude to convert it into a main signal output, and an amplifier (AMP) 41 for monitor output that amplifies the TIA output to convert it into a monitor output for monitoring of the received optical power (signal amplitude of input current).

The TIA 21 has a fixed gain in general, so that when a large optical power is input to the TIA 21, a large input protection circuit of the TIA 21 is activated and TIA output characteristics as shown in FIG. 9 are obtained. That is, as shown in FIG. 9, when an input optical power is smaller than a predetermined value Pmax, the TIA output becomes linear with respect to the received optical power, while when an input optical power is equal to or more than the predetermined value Pmax, the TIA output is saturated with respect to the received optical power and does not change. It follows that the rear-stage AMP 41 exhibits the same output characteristics, making it impossible to monitor the received optical power at the time when a large optical power is input. In this case, it is difficult for the TIA 21 to receive light over a wide dynamic range.

Under such circumstances, in order to achieve wide dynamic range, there has been proposed a circuit configuration in which the gain is made variable so as to keep a change in the amplitude of the TIA output within a predetermined range (refer to. e.g., Patent Document 1: JP-A-2004-260396 and Patent Document 2: JP-A-2005-086466) However, although the circuits disclosed in Patent Documents 1 and 2 have a means for switching the gain of the TIA 21, they are not designed for improving the characteristics of the AMP 41 for monitor output.

An optical receiving circuit according to a second related art shown in FIG. 8 has, in addition to the PD 11, TIA 21, and LIM 31 similar to those in the optical receiving circuit according to the first related art, a current mirror circuit 51 and a current-voltage conversion circuit (I-V circuit) 42 connected to the cathode of the PD 11 via the current mirror circuit 51. Such a circuit configuration is disclosed in e.g., Patent Document 3: JP-A-2006-319427.

In this circuit, the TIA 21 and LIM 31 constituting a main signal system and I-V circuit 42 and current mirror circuit 51 serving as circuits for monitoring received optical power are completely independent. In this configuration, received optical power is converted into current in the PD 11, while the current mirror circuit 51 causes current corresponding to current flowing in the PD 11 to be input to the I-V circuit 42. The I-V circuit 42 is a circuit for converting current into voltage, and the output of the I-V circuit 42 serves as the monitor output.

This circuit directly handles a copy of the current flowing in the PD 11 and, therefore, achieves a wide dynamic range. However, this circuit handles current on the cathode side of the PD 11, so that operating speed becomes lower in general due to existence of a bypass condenser or low-cut filter C connected to the cathode of the PD 11. Further, the response speed of the current mirror circuit 51 is not satisfactory.

As described above, the circuit of FIG. 7 has a problem in terms of a dynamic range, and the circuit of FIG. 8 has a problem in terms of responsiveness.

### SUMMARY OF INVENTION

An object of the present invention is to solve the above problems and to realize optical power monitoring capable of achieving a wide dynamic range and high-speed response. (0011) To achieve the above object, according to the present invention, there is provided an optical power monitoring circuit including: a first amplifier that amplifiers an input current from a light-receiving element with a variable gain to convert the current into a voltage signal; a second amplifier that amplifies the output of the first amplifier to convert the output into a main signal output; a third amplifier that amplifies the output of the first amplifier with a variable gain to convert the output into a monitor output; and a gain variable means for changing the gain of the first amplifier and gain of the third amplifier depending on the output of the first amplifier.

According to the present invention, optical power monitoring capable of achieving a wide dynamic range and high-speed response can be realized.

### BRIEF DESCRIPTION OF DRAWINGS

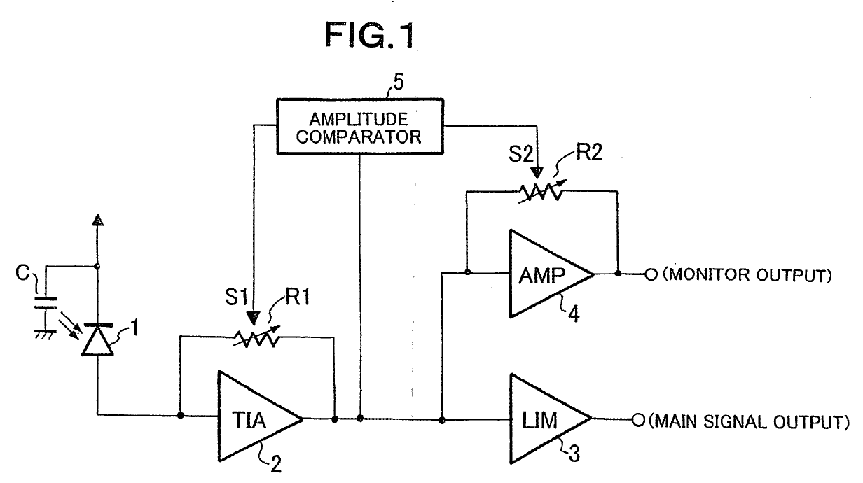

### {FIG. 1}

A block diagram showing a configuration of an optical module in which an optical power monitoring circuit according to a first example of the present invention is mounted.

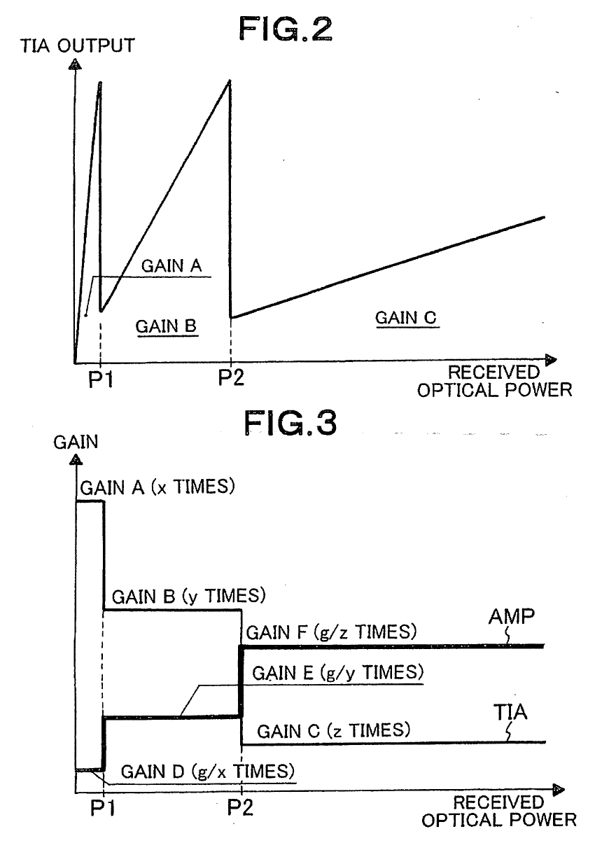

### {FIG. 2}

A graph showing gain variable characteristics of TIA with respect to received optical power.

### {FIG. 3}

A graph showing a relationship between gain variable characteristics of TIA and gain variable characteristics of AMP with respect to received optical power.

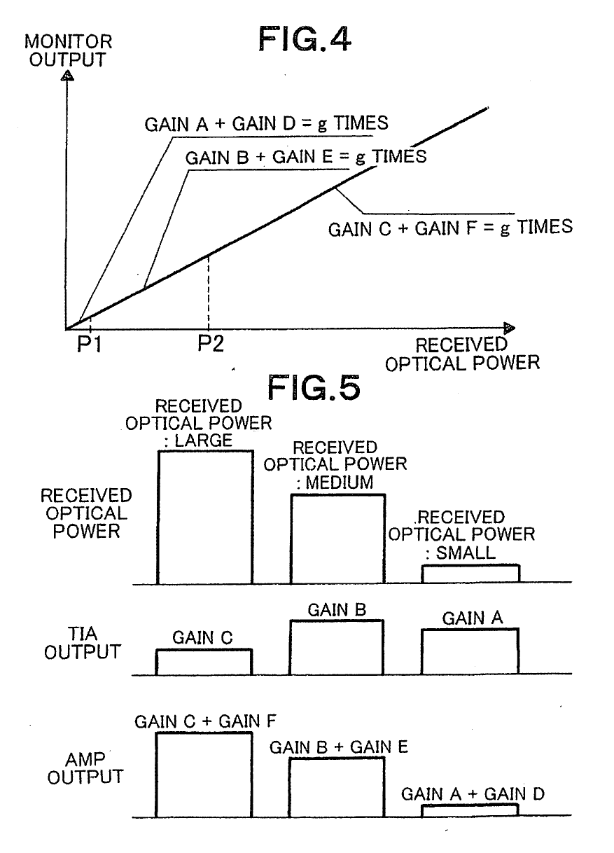

### {FIG. 4}

A graph showing an output voltage (monitor output) of AMP with respect to received optical power.

### {FIG. 5}

A view for explaining transition of the output amplitudes of TIA and AMP in the case where received optical power is large, medium, and small.

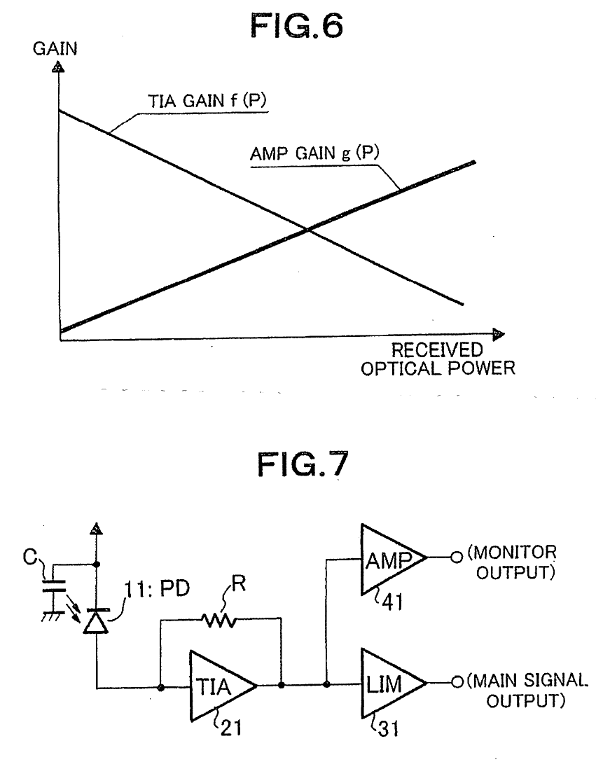

### {FIG. 6}

A graph showing gain variable characteristics of TIA and AMP with respect to received optical power adopted in an optical power monitoring circuit according to a second example of the present invention.

### {FIG. 7}

A block diagram showing a configuration of a circuit according to a first related art.

### {FIG. 8}

A block diagram showing a configuration of a circuit according to a second related art.

### {FIG. 9}

A graph showing TIA output characteristics of the circuit according to the first related art.

### DESCRIPTION OF EMBODIMENTS

A exemplary embodiment for practicing an optical power monitoring circuit, an optical transceiver, an optical module, an optical receiver, an amplifier circuit, and an integrated circuit will be described below with reference to the accompanying drawings.

An optical power monitoring circuit according to an exemplary embodiment of the present invention is mounted on an optical module having a receiver function. The optical module has a photodiode (hereinafter, abbreviated as “PD”) serving as a light receiving element that converts light into a current signal, a transimpedance amplifier (first amplifier, hereinafter abbreviated as “TIA”) serving as a preamplifier that receives the current signal from the PD and amplifies the current signal with a gain proportional to a value of a feedback resister to convert it into a voltage signal, a limiting amplifier (second amplifier, hereinafter abbreviated as “LIM”) serving as a post amplifier that amplifies the TIA output to a prescribed amplitude to convert it into a main signal output, and an amplifier (third amplifier, hereinafter abbreviated as “AMP”) for monitor output that receives the TIA output and amplifies the TIA output with a gain proportional to a value of a feedback resister to convert it into a monitor cutput for monitoring of the received optical power.

The TIA and AMP have their feedback resisters as variable resisters, respectively, and make the values of the feedback registers depending on a value of the TIA output, thereby controlling the gains thereof to optimum values.

The optical power monitoring circuit according to the present embodiment is a circuit provided in the optical module having a receiver function and capable of measuring the received optical power of the optical module over a wide dynamic range and at high speed.

In this circuit, received light is converted into current in the PD and then converted into voltage in TIA with an optimum gain thereof set depending on received optical power. The voltage output is then input to the LIM and AMP. The LIM demodulates a reception signal from the voltage output. The AMP amplifies or attenuates the voltage output depending on the variable gain of the TIA to thereby output a linear voltage with respect to the received optical power. That is, wide dynamic range optical power monitoring can be achieved by selecting an optimum gain in the TIA and, at the same time, a high-speed monitoring function can be achieved by measuring the TIA output voltage.

Thus, according to the present exemplary embodiment, by making the gains of the TIA and AMP variable, optical power monitoring capable of achieving a wide dynamic range and high-speed response can be realized.

In the present exemplary embodiment, a configuration may be adopted in which the gain of the TIA is made variable depending on the magnitude of received optical power corresponding to the TIA output and, at the same time, the gain of the AMP is made variable depending on the gain of the TIA. In this case, the gain of the AMP may be made variable depending on the gains of the TIA so that a monitor output becomes linear with respect to the received optical power. For example, the following configurations can be considered: a configuration in which the gain of the TIA is set to one of a plurality of predefined gain values depending on the magnitude of reception optical power corresponding to the TIA output, and the gain of the AMP is set to one of a plurality of predefined gains depending on the gain of the TIA; and a configuration in which the gains of the TIA and AMP are made continuously variable as a function of received optical power corresponding to the TIA output.

Examples of the present invention will be described below with reference to FIGS. 1 to 6.

### FIRST EXAMPLE

First, with reference to FIGS. 1 to 5, a first example of the present invention will be described.

An optical power monitoring circuit according to the present example is mounted on an optical module having a receiver function (receiver section). The optical module has a PD (light receiving element) 1 that converts light into a current signal, a TIA (first amplifier) 2 that receives the current signal from the PD 1 and amplifies the current signal with a gain proportional to a value of a feedback resister R1 to convert it into a voltage signal, a LIM (second amplifier) 3 that amplifies the TIA output to a prescribed amplitude to convert it into a main signal output, an AMP (third amplifier) 4 for monitor output that receives the TIA output and amplifies the TIA output with a gain proportional to a value of a feedback resister R2 to convert it into a monitor output for monitoring of the received optical power, and an amplitude comparator (gain variable means) 5. A reference symbol C denotes a bypass condenser or low-cut filter connected to the cathode of the PD1.

The amplitude comparator 5 receives the TIA output, compares the amplitude of the TIA output with a predefined threshold (amplitude reference value), and outputs, based on a result of the comparison, a first control instruction (control signal) S1 for controlling the gain of the TIA 2 depending on the magnitude of the TIA output and a second control instruction S2 for controlling the gain of the AMP 4 to the TIA 2 and AMP 4, respectively.

The TIA 2 has its feedback resister R1 as a variable resister, and controls, in response to the first control instruction S1 from the amplitude comparator 5, the value of the feedback register R1 to a gain value predefined depending on the value of the TIA output.

Similarly, the AMP 4 has its feedback resister R2 as a variable resister, and controls, in response to the second control instruction S2 from the amplitude comparator 5, the value of the feedback register R2 to a gain value predefined depending on a value of the TIA output.

The amplifiers constituting the amplifier circuit of the receiver section of the optical module shown in FIG. 1, i.e., the TIA 2, LIM 3, and AMP 4, may be separately integrated into individual ICs (integrated circuits), or alternatively, all of the amplifiers may be integrated into one IC. The amplifier comparator 5maybe formed integrally in an IC constituting the amplifier circuit, or in an IC constituting a not-shown controller or the like, or may be formed using a dedicated IC.

Next, operation of the present example will be described.

Light input to the optical module shown in FIG. 1 is converted into a current signal in the PD 1. The current signal is then input to the TIA 2, where it is converted into a voltage signal.

FIG. 2 explains switching operation of the gain of the TIA 2 performed at that time. Here, for easy understanding, a case where a circuit that digitally switches the gain of the TIA 2 between three values is adopted will be described. Note that a case where he gain of the TIA 2 is switched between two values or between four or more values may be applied to the present invention.

In the example of FIG. 2, it is assumed that the gain of the TIA 2 can be switched between gain A, gain B, and gain C. The TIA 2 can change the value of the feedback resistance R1 and thereby selects the gain depending on received optical power, i.e., current input to the TIA 2. In this case, the TIA output is input to the amplifier comparator 5 where the TIA output is compared with predefined first and second thresholds of received optical power (input current). Based on a result of the comparison, the first control instruction S1 is issued to switch the gain of the TIA to again corresponding to the TIA output. In the example of FIG. 2, gain A is selected when the reception optical power is smaller than a first threshold P1, gain B is selected when the reception optical power is medium, i.e., larger than the first threshold P1 and smaller than then a second threshold P2, and gain C is selected when the reception optical power is larger than the second threshold P2. The gain of the TIA 2 is selected from among the three gains A, B, and C in this manner depending on the magnitude of the received optical power, so that the TIA output is not saturated, making it possible to receive optical power over a wide dynamic range.

The TIA output is then input to the. LIM 3 and AMP 4.

In the LIM 3, the TIA output is amplified to a prescribed amplitude. The function of the LIM 3, which is a basic function of an optical module, is known, and details thereof are omitted here.

In the AMP 4, the TIA output is converted into a monitor output. At this time, since the gain switching has been carried out in the TIA 2, the signal intensity of the TIA output is changed by the applied gain as shown in FIG. 2. Thus, the AMP 4 amplifies or attenuates the TIA output depending on the gain of the TIA 2. That is, as in the case of the gain switching in the TIA 2, the gain of the AMP 4 is switched to a gain corresponding to the TIA output based on the second control instruction S2 from the amplitude comparator 5.

FIG. 3 is a graph showing a relationship between the gain of the TIA 2 and gain of the AMP 4. Here, it is assumed that the total gain of the TIA 2 and AMP 4 is set to g times. In the example of FIG. 3, assuming that the gain of the TIA 2 for gain A is set to x times, gain D of the AMP 4 at that time is set to g/x times. As a result, the total gain becomes g times. Similarly, assuming that the gains of the TIA 2 for gain B and gain C are set to y times and z times, gain E and gain F of the AMP 4 are set to g/y times and g/z times. As a result, the total gain becomes g times in the entire range of the reception optical power.

FIG. 4 shows an output voltage of the AMP 4 at that time. As described above, the AMP 4 amplifies or attenuates the TIA output depending on the gain of the TIA 2 to thereby output a linear voltage amplitude with respect to the received optical power.

FIG. 5 is a view showing transition of the amplitudes of the TIA output and AMP output. When the received optical power is larger than the second threshold P2, gain C is selected as the gain of the TIA 2. Similarly, when the reception optical power is medium, i.e., larger than the first threshold P1 and smaller than then a second threshold P2, and when the reception optical power is smaller than the first threshold P1, gains corresponding to the received optical power are selected. As described above, the amplitude of the TIA output differs depending on the selected gain. Then, as the gain of the AMP 4, a gain corresponding to the gain of the TIA 2 is selected (for example, gain D is selected in the case where gain A is selected as the gain of the TIA 2), and the AMP output is converted into an output amplitude proportional to the received optical power. The TIA output operates at extremely high speed. Thus, in the present example, monitoring of the TIA output can realize optical power monitoring capable of achieving high-speed response.

Thus, according to the present example, received light is converted into current by the PD 1 and then converted into voltage with an optimum gain of the TIA 2. The optimum gain is determined by the TIA output input to the amplitude comparator 5. The TIA output is then input to the LIM 3 and AMP 4. The LIM 3 demodulates a received signal and outputs the signal with a prescribed amplitude. The AMP 4 amplifies or attenuates the TIA output depending on the variable gain of the TIA 2 to thereby output a linear voltage level with respect to the received optical power.

According to the present example, the following effects can be obtained.

1)The first effect is that switching of the gains of the TIA 2 and AMP 4 depending on the TIA output allows the received optical power to be monitored over a wide dynamic range.

2) The second effect is that the AMP 4 monitors a TIA output capable of achieving high-speed response to thereby allow monitoring of the received optical power at high-speed.

3) The third effect is that the optical power monitoring circuit including the TIA 2, LIM 3, and AMP 4 can be formed integrally in an IC of the receiver section of the optical module to thereby reduce the number of parts.

As described above, according to the present example, by making the gains of the TIA and AMP 4 variable, optical power monitoring capable of achieving a wide dynamic range and high-speed response can be realized.

### SECOND EXAMPLE

With reference FIG. 6, a second example of the present invention will be described.

In the present example, the gain variable characteristics of the TIA 2 and AMP 4 differ from those shown in FIG. 3.

FIG. 6 shows gain variable characteristics of TIA 2 adopted in the present example. As shown in FIG. 6, the gain of the TIA 2 is made continuously variable using a function f (P) of the received optical power P and, at the same time, the gain of the AMP 4 is made variable using a function g (P) of the received optical power P. As a result, as in the case of the first example, optical power monitoring capable of achieving a wide dynamic range and high-speed response can be realized.

Although the optical power monitoring circuit capable of measuring the received optical power over a wide dynamic range and at high speed is applied to an optical module having a receiver function in the above exemplary embodiment and examples, the monitoring circuit may be applied to a single optical receiver (optical receiver module) or may be applied to an optical transceiver integrally including the optical receiver and an optical transmitter (optical transmitter module) for converting an electrical signal into light. In this case, in the optical transmitter module of the optical transceiver, a semiconductor laser such as an LD (Laser Diode) may be adopted as a light-emitting device and, in this case, an LD driver for driving the LD may be provided. Further, the optical power monitoring circuit may be applied to an amplifier circuit used in an optical receiver or a semiconductor device such as an IC (Integrated Circuit) including the amplifier circuit.

The present invention may be applied to an optical module, optical transceiver, optical receiver, amplifier circuit, integrated circuit used in the field of optical communication.

While the invention has been particularly shown and described with reference to the exemplary embodiments and examples thereof, the invention is not limited to these exemplary embodiments and examples. It will be understood by those of ordinary skill in the art that various changes in form and details may be made therein without departing from the spirit and scope of the present invention as defined by the claims.

1. An optical power monitoring circuit comprising:
a first amplifier that amplifies an input current from a light-receiving element with a variable gain to convert the current into a voltage signal;
a second amplifier that amplifies the output of the first amplifier to convert the output into a main signal output;
a third amplifier that amplifies the output of the first amplifier with a variable gain to convert the output into a monitor output; and
gain variable means for changing the gain of the first amplifier and gain of the third amplifier depending on the output of the first amplifier.

2. The optical power monitoring circuit according to claim 1, wherein
the gain variable means changes the gain of the first amplifier depending on the magnitude of the received optical power corresponding to the output of the first amplifier and changes the gain of the third amplifier depending on the gain of the first amplifier.

3. The optical power monitoring circuit according to claim 2, wherein
the gain variable means changes the gain of the first amplifier depending on the magnitude of the received optical power corresponding to the output of the first amplifier and changes the gain of the third amplifier depending on the gain of the first amplifier so that the monitor output becomes linear.

4. The optical power monitoring circuit according to claim 3, wherein
the gain variable means sets the gain of the first amplifier to one of a plurality of predefined gain values depending on the magnitude of the reception optical power corresponding to the output of the first amplifier and sets the gain of the third amplifier to one of a plurality of predefined gain values depending on the gain of the first amplifier.

5. The optical power monitoring circuit according to claim 1, wherein
the gain variable means continuously changes the gains of the first and third ampifiers as a function of the received optical power corresponding to the output of the first amplifier.

6. The optical power monitoring circuit according to claim 1, wherein
the first amplifier is a transimpedance amplifier, and
the second amplifier is a limiting amplifier.

7. An optical module comprising the optical power monitoring circuit as claimed in claim 1.

8. An optical transceiver comprising the optical power monitoring circuit as claimed in claim 1.

9. An optical receiver comprising the optical power monitoring circuit as claimed in claim 1.

10. An amplifier circuit comprising:
a first amplifier that amplifies an input current from a light-receiving element with a variable gain to convert the current into a voltage signal;
a second amplifier that amplifies the output of the first amplifier to convert the output into a main signal output;
a third amplifier that amplifies the output of the first amplifier with a variable gain to convert the output into a monitor output; and
gain variable means for changing the gain of the first amplifier and gain of the third amplifier depending on the output of the first amplifier.

11. An integrated circuit comprising an amplifier circuit as claimed in claim 10.
